(19) United States
(12) Patent Application Publication
(10) Pub. No.: US 2025/0245406 A1
(43) Pub. Date: Jul. 31, 2025

(54) FUZZY CLOUD-BASED RISK ASSESSMENT METHOD FOR RESERVOIR OPERATION SCHEMES

(71) Applicant: China Institute of Water Resources and Hydropower Research, Beijing (CN)

(72) Inventors: Boran Zhu, Beijing (CN); Junqiang Lin, Beijing (CN); Di Zhang, Beijing (CN); Hui Cao, Beijing (CN); Zhengfeng Bao, Beijing (CN); Yufeng Ren, Beijing (CN); Yiming Ma, Beijing (CN); Qidong Peng, Beijing (CN); Tiantian Jin, Beijing (CN); Youkun Li, Beijing (CN); Shaogeng Zhang, Beijing (CN); Xin Ma, Beijing (CN)

(73) Assignee: China Institute of Water Resources and Hydropower Research, Beijing (CN)

(21) Appl. No.: 18/977,853

(22) Filed: Dec. 11, 2024

(30) Foreign Application Priority Data
Jan. 25, 2024 (CN) 202410105798.X

(51) Int. Cl. G06F 30/28

(52) U.S. Cl. CPC G06F 30/28

(57) ABSTRACT

A fuzzy cloud-based risk assessment method for reservoir operation schemes, including: collecting basic data of target reservoirs; constructing optimal operation model of conventional reservoirs to obtain model calculation results; acquiring change process of operation characteristics during whole operating period according to model calculation results, and constructing multi-level reservoir multi-dimensional risk assessment index system; dividing different risk level intervals according to multi-level reservoir multi-dimensional risk assessment index system; obtaining large number of sample data xᵢⱼ of reservoir risk index under corresponding working conditions by multiple parallel calculations to conduct risk assessment; calculating cloud digital features of different indexes by inverse cloud generator; and weighting indexes in index layer and criterion layer by Analytic Hierarchy Process to obtain multi-dimensional risk assessment results. In order to promote sustainable development and utilization of water resources and enhance level of reservoir risk management, scientific evaluation of reservoir risk is conducted by comprehensively considering various uncertainties.

### CROSS-REFERENCE TO RELATED APPLICATION

This application claims the priority benefit of China application serial no. 202410105798.X, filed on Jan. 25, 2024. The entirety of the above-mentioned patent application is hereby incorporated by reference herein and made a part of this specification.

### TECHNICAL FIELD

The present invention relates to the field of water resources in the discipline of water conservancy engineering, and more particularly, to a fuzzy cloud-based risk assessment method for reservoir operation schemes.

### BACKGROUND

As the main tool for the development and utilization of water resources, reservoirs play the comprehensive utilization benefits of water resources such as flood control, power generation, water supply and ecology by regulating the flow process of rivers. However, in the operation process, it is inevitable that the operation targets cannot reach the expected risk events, such as water level overrun, unstable power generation and insufficient water supply, due to natural conditions, engineering conditions and man-made scheduling operations, which will affect the sustainable development and utilization of water resources and even threaten the people's life and property safety in severe cases. Accurate assessment of reservoir risk under different operating conditions is helpful to realize scientific decision-making of reservoir operation schemes and guarantee the sustainable development and utilization of water resources in the watershed, which is of great significance to regional economic development.

The common framework of reservoir risk assessment is based on the simulation results of reservoir operation in a future period, constructing the corresponding index system to quantify the target risk, and then combining with the specific risk criteria for judgment, so as to obtain the reservoir target risk assessment results under specific working conditions. However, the existing reservoir risk assessment methods have the following deficiencies.

(1) The calculation of reservoir operation scheme is easily affected by the initial population distribution of different algorithms and the iterative randomness of parameters, causing uncertainty to the simulation results. In addition, when integrating multi-target risks, the comprehensive risk is calculated by the direct weighted summation method, and then the risk level is judge artificially by the corresponding standard. Both in the process of weighting and risk rating are influenced by human subjective factors, and there is a large fuzzy uncertainty. At present, the reservoir risk assessment lacks a scientific assessment method which can consider multiple uncertainties.

(2) When quantifying the risk characterization, the probability of risk event occurrence in the simulation results is taken as the risk characterization index, only the probability of risk occurrence is quantified, and the consequence of risk events and the restoration process are not quantified.

### SUMMARY

In view of the above problems, the present invention has been developed to provide a fuzzy cloud-based risk assessment method for reservoir operation schemes which overcomes or at least partially solves the above problems.

According to an aspect of the present invention, a fuzzy cloud-based risk assessment method for reservoir operation schemes is provided, the risk assessment method including:
collecting basic data of target reservoirs;
constructing an optimal operation model of conventional reservoirs to obtain model calculation results;
acquiring the change process of the operation characteristics during the whole operating period according to the model calculation results, and constructing a multi-level reservoir multi-dimensional risk assessment index system;
dividing different risk level intervals according to the multi-level reservoir multi-dimensional risk assessment index system;
obtaining a large number of sample data of the reservoir risk index under corresponding working conditions by multiple parallel calculations to conduct the risk assessment;
calculating cloud digital features of different indexes by the inverse cloud generator; and
weighting the indexes in the index layer and the criterion layer by the Analytic Hierarchy Process (AHP), and respectively calculating the Pythagoras fuzzy cloud of each index in the criteria layer and the target layer to obtain the multi-dimensional risk assessment results of the target working condition.

Optionally, the collecting the basic data of the target reservoirs specifically includes:
collecting operation regulation, a relationship curve of water level and reservoir capacity, a relationship curve of leakage flow and tail water, and a discharge capacity curve of each discharge facility of the target reservoirs.

Optionally, the constructing the optimal operation model of conventional reservoirs to obtain the model calculation results specifically includes:
constructing the optimal operation model of conventional reservoirs, considering inflow conditions and engineering conditions that need risk assessment, and transforming same into constraint conditions or boundary input of the model; and
generating the optimal operation schemes of reservoirs under corresponding working conditions by solving.

Optionally, the operation features during the whole operating period specifically include a reservoir discharged volume, a reservoir water level, an output and a water level variation.

Optionally, the constructing the multi-level reservoir multi-dimensional risk assessment index system specifically includes:
constructing the multi-level reservoir multi-dimensional risk assessment index system by the risk characterization method of reliability, resilience and vulnerability;
defining Xₜ as a performance state in some aspect of an assessment object at a moment t; when the system performance is in a normal state NS, Xₜ is assigned to 1; when the system performance is in an impaired state FS, Xₜ is assigned to 0;
wherein the reliability of the system in terms of performance in some aspect can be expressed as:

$$α = P [ {X}_{t} ∈ NS ] = \frac{{\sum }_{t = 1}^{T} {X}_{t}}{T} ; \qquad ( Formula 1 )$$

in the formula, α is a reliability index, and T is the total time of the whole simulation period;
the resilience represents the possibility of the assessment object restored from the impaired state to the normal state, and is calculated according to the number of performance restoration in the operation period:

$$W ( t ) = \{ \begin{matrix}1 , if {X}_{t} = 0 and {X}_{t + 1} = 1 \\ 0 , otherwise\end{matrix} ; \qquad ( Formula 2 )$$

$$γ = \{ \begin{matrix}P [ {X}_{t + 1} ∈ NS \vert {X}_{t} ∈ FS ] = \frac{{\sum }_{t = 1}^{T} W ( t )}{T - {\sum }_{t = 1}^{T} X ( t )} & if α < 1 \\ 1 & if α = 1\end{matrix} ; \qquad ( Formula 3 )$$

in the formula, γ represents the resilience of the assessment object, and W(t) represents the number of times of system restoration; the performance restoration without impairment in the operating period is defined as 1;
the vulnerability index is a measure of the severity of a failure, expressed as the average of the maximum performance loss of all risk events over the entire operating period:

$$ϑ = \frac{{\sum }_{j = 1}^{M} {V}_{j}}{M} ; \qquad ( Formula 4 )$$

in the formula, v represents the vulnerability of the assessment object and Vⱼ represents the maximum loss of performance per risk event; and M represents the total number of risk events in the whole simulation period.

Optionally, the dividing different risk level intervals according to the multi-level reservoir multi-dimensional risk assessment index system specifically includes:
dividing different risk levels based on the multi-dimensional risk assessment index system of the constructed cascade reservoirs;
according to upper and lower boundaries of different risk level intervals, determining cloud digital features (Eₓ, Eₙ, Hₑ) of the different risk levels and a Pythagoras fuzzy number <μ_{P}(x), v_{P}(x)> of the corresponding interval by a forward cloud generator (Formula 5):

$$\{ \begin{matrix}{E}_{x} = ( {U}_{min} + {U}_{max} ) / 2 \\ {E}_{n} = ( {U}_{max} - {U}_{min} ) / 6 \\ {H}_{e} = k \cdot {E}_{n}\end{matrix} . \qquad ( Formula 5 )$$

In the formula, Ex refers to the expected distribution of cloud droplets in a domain space, which is a most representative point of the qualitative concept; En refers to the dispersion degree of cloud droplets, which is the measurable granular representation of qualitative concept; generally, the larger En is, the more macroscopic the qualitative concept is, that is, the greater the fuzziness of qualitative concept is; He represents the uncertainty of entropy; the greater the He is, the greater the thickness of cloud droplets, and the greater the degree of dispersion is, which indicates that the simulation results are more random; Uₘᵢₙ and Uₘₐₓ respectively represent the minimum value and the maximum value of the risk level threshold; and k represents an adjustment system for cloud droplet cohesion, and is usually taken as k=0.1 by default.

Optionally, the calculating cloud digital features of different indexes by the inverse cloud generator specifically includes:
calculating the cloud digital features (Exᵢ, Enᵢ, Heᵢ) of different indexes by the inverse cloud generator (Formula 6);
determining a Pythagoras fuzzy number of each index of an index layer based on the risk level interval to which the sample data of the index layer belongs, and obtaining a Pythagoras fuzzy cloud PFCᵢ(<Exᵢ, μ_{Pi}(x), v_{Pi}(x)>, Enᵢ, Heᵢ) (i=1, 2, . . . , m) of different indexes of the index layer;

$$\{ \begin{matrix}{E}_{x} ( i ) = \frac{1}{n} {\sum }_{j = 1}^{n} {x}_{ij} \\ {E}_{n} ( i ) = \sqrt{\frac{π}{2}} \times \frac{1}{n} {\sum }_{j = 1}^{n} \vert {x}_{ij} - {E}_{x} ( i ) \vert \\ {H}_{e} ( i ) = \sqrt{\vert {S ( i )}^{2} - {{E}_{n} ( i )}^{2} \vert}\end{matrix} ( i = 1 , 2 , L , m ; j = 1 , 2 , L , n ) ; \qquad ( Formula 6 )$$

in the formula, xᵢⱼ is the value of the index i in a j^{th} simulation result;

$${S ( i )}^{2} = \frac{1}{n - 1} {\sum }_{j = 1}^{n} {( {x}_{ij} - {E}_{x} ( i ) )}^{2}$$

represents a variance of the simulation sample; μ_{Pi}(x) is a membership value of the index i; and v_{Pi}(x) is a non-membership value of the index i.

Optionally, the weighting the indexes in the index layer and the criterion layer by the Analytic Hierarchy Process (AHP), and respectively calculating the Pythagoras fuzzy cloud of each index in the criteria layer and the target layer to obtain the multi-dimensional risk assessment results of the target working condition, including:
weighting the indexes in the index layer and the criterion layer by the Analytic Hierarchy Process (AHP), and respectively calculating the Pythagoras fuzzy cloud (Formula 7) of each index in the criteria layer and the target layer to obtain the multi-dimensional risk assessment results of the target working condition;

$$PFC ( {PFC}_{1} , {PFC}_{2} , … , {PFC}_{m} ) = {\sum }_{i = 1}^{m} {ω}_{i} {PFC}_{i} = ( < {\sum }_{i = 1}^{m} {ω}_{i} {Ex}_{i} , \frac{{\sum }_{i = 1}^{m} {ω}_{i} {μ}_{Pi} {Ex}_{i}}{{\sum }_{i = 1}^{m} {ω}_{i} {Ex}_{i}} , \frac{{\sum }_{i = 1}^{m} {ω}_{i} {v}_{Pi} {Ex}_{i}}{{\sum }_{i = 1}^{m} {ω}_{i} {Ex}_{i}} > , \sqrt{{\sum }_{i = 1}^{m} {{ω}_{i} ( {En}_{i} )}^{2}} , \sqrt{{\sum }_{i = 1}^{m} {{ω}_{i} ( {He}_{i} )}^{2}} ) ; \qquad ( Formula 7 )$$

in the formula, PFCᵢ represents the Pythagoras fuzzy cloud of the index i; ωᵢ represents the weight of the index i; Exᵢ represents the expected distribution of cloud droplets of the index i, the point representing the qualitative concept; μ_{Pi} represents the membership of the index i; v_{Pi} represents the non-membership of the index i; Enᵢ represents the entropy of the index i to describe the degree of dispersion of cloud droplets; and Heᵢ represents the super-entropy of the index i to describe the uncertainty of the qualitative concept.

The present invention provides a fuzzy cloud-based risk assessment method for reservoir operation schemes, the risk assessment method including: collecting basic data of target reservoirs; constructing an optimal operation model of conventional reservoirs to obtain model calculation results; acquiring the change process of the operation characteristics during the whole operating period according to the model calculation results, and constructing a multi-level reservoir multi-dimensional risk assessment index system; dividing different risk level intervals according to the multi-level reservoir multi-dimensional risk assessment index system; obtaining a large number of sample data xᵢⱼ of the reservoir risk index under corresponding working conditions by multiple parallel calculations to conduct the risk assessment; calculating cloud digital features of different indexes by the inverse cloud generator; and weighting the indexes in the index layer and the criterion layer by the Analytic Hierarchy Process (AHP), and respectively calculating the Pythagoras fuzzy cloud of each index in the criteria layer and the target layer to obtain the multi-dimensional risk assessment results of the target working condition. In order to promote the sustainable development and utilization of water resources and enhance the level of reservoir risk management, the scientific evaluation of reservoir risk is conducted by comprehensively considering various uncertainties.

The above description is merely an overview of the technical aspects of the disclosure, which can be carried out in accordance with the contents of the description in order to make the technical aspects of the disclosure more clearly understood. The detailed description of the disclosure will be described below to make the above and other objects, features and advantages of the disclosure more apparent.

### BRIEF DESCRIPTION OF THE DRAWINGS

In order to more clearly describe the technical solutions in the embodiments of the invention, the drawings to be used in the description of the embodiments will be briefly introduced below. It will be apparent to those skilled in the art that the drawings in the following description are only some of the invention, and that other drawings may be obtained from the drawings without any creative works.

FIG. 1 shows a flowchart of a fuzzy cloud-based risk assessment method for reservoir operation schemes according to an embodiment of the present invention;

FIG. 2 shows a schematic diagram illustrating a reservoir multi-dimensional risk assessment index system according to an embodiment of the present invention;

FIG. 3 shows an example view of a reservoir multi-dimensional risk assessment index system according to an embodiment of the present invention;

FIG. 4 shows Pythagoras fuzzy cloud risk assessment results on an index layer according to an embodiment of the present invention;

FIG. 5 shows Pythagoras fuzzy cloud risk assessment results on a criteria layer according to an embodiment of the present invention; and

FIG. 6 shows Pythagoras fuzzy cloud risk assessment results on a target layer according to an embodiment of the present invention.

### DESCRIPTION OF THE EMBODIMENTS

Exemplary embodiments of the present invention are described in more detail below with reference to the accompanying drawings. While the drawings show exemplary embodiments of the present disclosure, it should be understood that the present disclosure may be embodied in various forms and should not be construed as limited to the embodiments set forth herein. Rather, these embodiments are provided so that this disclosure will be thorough and complete, and will fully convey the scope of the disclosure to those skilled in the art.

The terms “comprises” and “having”, and any variation thereof, in the embodiments of the description, the claims and the drawings of the invention are intended to cover a non-exclusive inclusion, such as a list of steps or elements.

Hereinafter, embodiments of the present invention will be described in detail with reference to the accompanying drawings.

### Embodiment 1

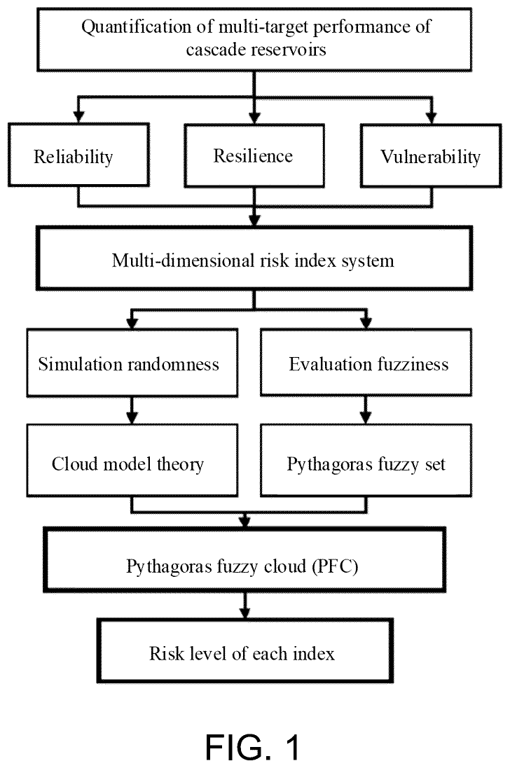

As shown in FIG. 1, a fuzzy cloud-based risk assessment method for reservoir operation schemes specifically includes the steps below.

The basic data is collected, such as operation regulation, a relationship curve of water level and reservoir capacity, a relationship curve of leakage flow and tail water, and a discharge capacity curve of each discharge facility of the target reservoirs.

The optimal operation model of conventional reservoirs is constructed, and when considering inflow conditions and engineering conditions that need risk assessment, the same is transformed into constraint conditions or boundary input of the model to generate the optimal operation schemes of reservoirs under corresponding working conditions by solving.

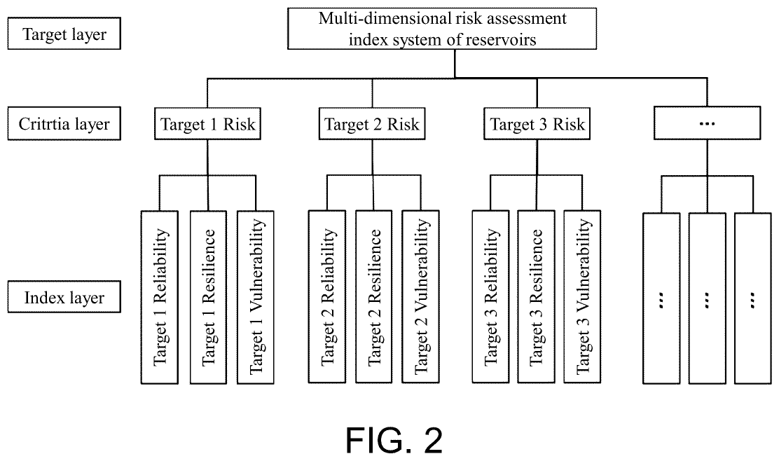

The changing process of reservoir discharge volume, reservoir water level and output during the whole operating period is obtained from the calculation results of the model, and the multi-target performance of the reservoir is quantified. The multi-level reservoir multi-dimensional risk assessment index system is constructed by the risk characterization method of reliability (Formula 1), resilience (Formula 3) and vulnerability (Formula 4), as shown in FIG. 2.

Xₜ is defined as a performance state in some aspect of an assessment object at a moment t; when the system performance is in a normal state (NS), Xₜ is assigned to 1; and when the system performance is in an impaired state (FS), Xₜ is assigned to 0.

The reliability of the system in terms of performance in some aspect can be expressed as:

$$α = P [ {X}_{t} ∈ NS ] = \frac{{\sum }_{t = 1}^{T} {X}_{t}}{T} ; \qquad ( Formula 1 )$$

in the formula, α is a reliability index, and T is the total time of the whole simulation period;
the resilience represents the possibility of the assessment object restored from the impaired state to the normal state, and is calculated according to the number of performance restoration in the operating period:

$$W ( t ) = \{ \begin{matrix}1 , & if {X}_{t} = 0 and {X}_{t + 1} = 1 \\ 0 , & otherwise\end{matrix} ; \qquad ( Formula 2 )$$

$$γ = \{ \begin{matrix}P [ {X}_{t + 1} ∈ NS \vert {X}_{t} ∈ FS ] = \frac{{\sum }_{t = 1}^{T} W ( t )}{T - {\sum }_{t = 1}^{T} X ( t )} & if α < 1 \\ 1 & if α = 1\end{matrix} ; \qquad ( Formula 3 )$$

in the formula, γ represents the resilience of the assessment object, and W(t) represents the number of times of system restoration; the performance restoration without impairment in the operating period is defined as 1;
the vulnerability index is a measure of the severity of a failure, expressed as the average of the maximum performance loss of all risk events over the entire operating period:

$$ϑ = \frac{{\sum }_{j = 1}^{M} {V}_{j}}{M} ; \qquad ( Formula 4 )$$

in the formula, v represents the vulnerability of the assessment object and Vⱼ represents the maximum loss of performance per risk event; and M represents the total number of risk events in the whole simulation period.

### Embodiment 2

(1) The basic data is collected, such as operation regulation (including a water level, flow, an output and other requirements and operation principles in different operating periods in the year), a relationship curve of water level and reservoir capacity, a relationship curve of leakage flow and tail water, and a discharge capacity curve of each discharge facility of a reservoir.

(2) The optimal operation model of conventional reservoirs is constructed, and when considering inflow conditions and engineering conditions that need risk assessment, the same is transformed into constraint conditions or boundary input of the model. In this example, the maximum power generation in the operating period is taken as the objective function, the flood year runoff condition is taken as the model boundary input, and the engineering fault scenario is set as that the gate fault at the beginning of flood period leads to ⅓ reduction of discharge capacity. There is a maintenance period of three months. The model is built and described as follows:

Objective function:

$$f = max {\sum }_{t = 1}^{r} {N}_{t} \cdot Δ t$$

Constraint condition: Zₜ^{min}, Zₜ, Zₜ^{max}

$${V}_{t + 1} - {V}_{t} = ( {Q}_{t}^{in} - {Q}_{t}^{out} ) \cdot Δ t$$

Qₜ^{min}, Qₜ^{out}, Qₜ^{max}

Nₜ^{min}, Nₜ, Nₜ^{max}
in the formula, Nₜ is the unit output of the reservoir in the time period t; Zₜ is the length of the time period; Zₜ is the average water level of the reservoir in the time period t; Zₜ^{min} and Zₜ^{max} are the minimum water level and the maximum water level allowed by the reservoir in the time period t, respectively; Vₜ₊₁ and Vₜ are the average storage capacity of reservoirs in the time periods t+1 and t, respectively; Qₜⁱⁿ and Qₜ^{out} are the inflow and outflow of the reservoir in the time period t, respectively; in this example, Qₜⁱⁿ is the runoff process of a flood year; Qₜ^{min} and Qₜ^{max} are the minimum and maximum discharge flows allowed by the reservoir within the time period t; Qₜ^{max} is ⅔ of the designed maximum discharge capacity of the reservoir within three months after the beginning of the flood season in this example; Nₜ^{min} and Nₜ^{max} and are the minimum output and the maximum output allowed by the reservoir in the time period t.

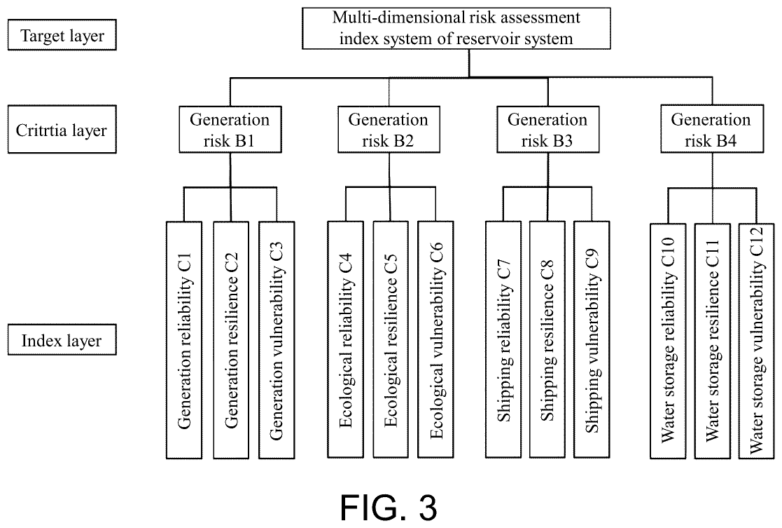

When the multi-level reservoir multi-dimensional risk assessment index system is constructed, in this example, four targets of reservoir power generation, ecology, shipping and water storage are taken as the multi-target performance, forming a multi-dimensional risk assessment index system as shown in FIG. 3.

We determine different risk levels, assign values to the Pythagoras fuzzy numbers in different level intervals, and calculate the cloud digital features of different levels by Formula 5. In this example, the range [0, 100] is divided into five risk levels: low, low, medium, relatively high and high. The cloud digital features are calculated by the Pythagoras fuzzy numbers of different levels with reference to relevant literatures. The results are shown in Table 1.

TABLE 1
Risk level of Pythagoras fuzzy cloud

| | | | | | Pythagoras fuzzy | |
|---|---|---|---|---|---|---|
| | Risk | Cloud digital feature | | | number | |
| Risk level | interval | Eₓ | Eₙ | Hₑ | μ | ν |
| Low Risk | [0, 20] | 10 | 3.33 | 0.33 | 0.100 | 0.943 |
| Low Risk | [20, 40] | 30 | 3.33 | 0.33 | 0.300 | 0.900 |
| Medium risk | [40, 60] | 50 | 3.33 | 0.33 | 0.500 | 0.806 |
| Higher risk | [60, 80] | 70 | 3.33 | 0.33 | 0.700 | 0.641 |
| High risk | [80, 100] | 90 | 3.33 | 0.33 | 0.900 | 0.300 |

The parallel calculations for 10 times are performed on the constructed operation model, and the sample data of risk assessment is obtained from the simulation results.

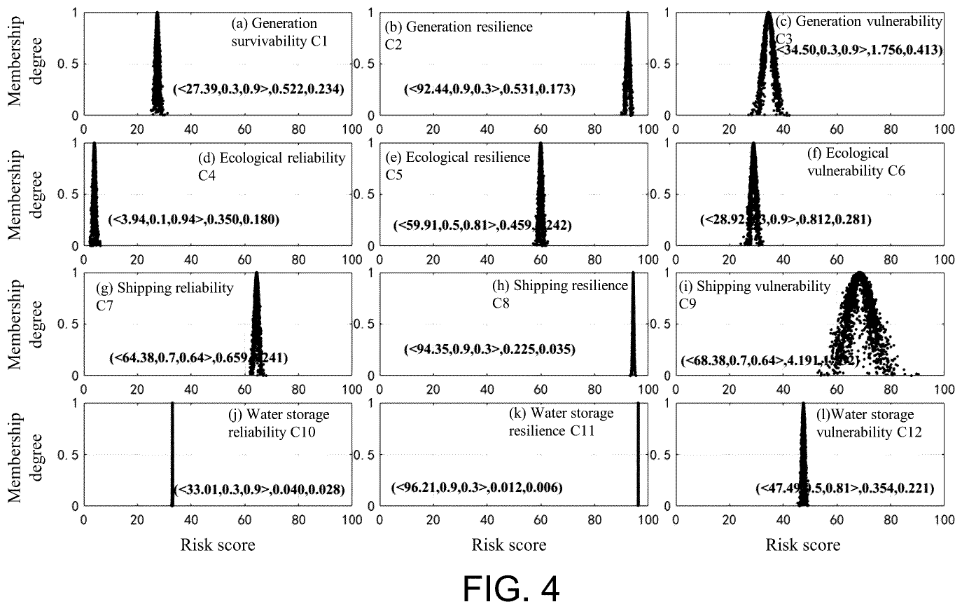

Based on the risk assessment samples, the risk Pythagoras fuzzy cloud of each index in the index layer of the multi-dimensional risk assessment index system of the reservoir is calculated according to Formula 6. As shown in FIG. 4, the risk level of each index is reflected by the expected value in the cloud digital feature. In this example, the ecological reliability is at a low risk level. The generation reliability, generation vulnerability, ecological vulnerability and water storage reliability are all at a low risk level. The water storage vulnerability is at a medium risk level. The ecological resilience, shipping reliability and shipping vulnerability are at relatively high risk levels. The power generation resilience, the shipping resilience and the water storage resilience are at high risk levels. The randomness of the results is intuitively expressed by the dispersion degree of scatter points in the cloud chart. In the exemplary working condition, the simulation randomness of the shipping vulnerability is the highest, and the simulation randomness of the water storage resilience is the lowest. The fuzzy uncertainty in the results is quantified by the Pythagoras fuzzy number. The fuzziness is low if the membership degree is high. In the exemplary working condition, the indexes with the lowest fuzzy degree are shipping resilience and water storage resilience, and the membership degree is 0.9. The indexes with the highest fuzziness are ecological reliability, and the membership degree is only 0.1.

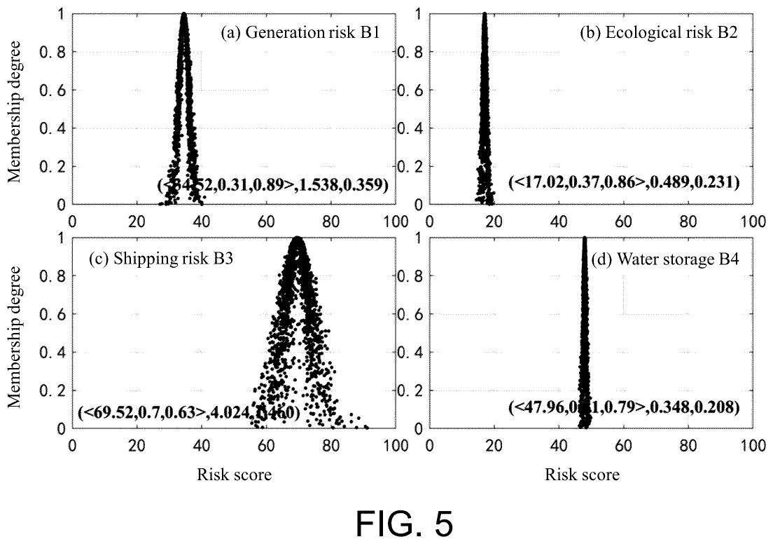

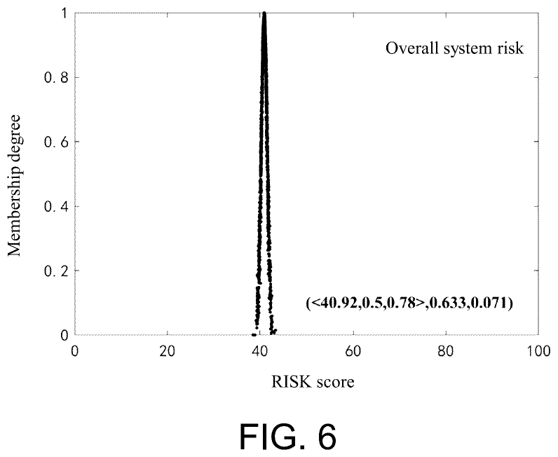

The indexes in the index layer and the criterion layer are weighted by the Analytic Hierarchy Process (AHP), and the calculation results of the weights are shown in Table 2. According to Formula 7, the Pythagoras fuzzy clouds of each index of the criteria layer and the target layer are respectively calculated, so as to obtain the multi-dimensional risk assessment results of the criteria layer and the target layer under the target working condition, as shown in FIGS. 5 and 6.

TABLE 2
Weight values of multi-dimensional risk
assessment index system of reservoirs

| | Criteria layer | | Index layer | |
|---|---|---|---|---|
| Target layer | Index name | Weight | Index name | Weight |
| Multi- | Generation | 0.298 | Generation reliability C1 | 0.248 |
| dimensional | risk B1 | | Generation resilience C2 | 0.007 |
| risk | | | Generation | 0.745 |
| assessment | | | vulnerability C3 | |
| index | Ecological | 0.189 | Ecological reliability C4 | 0.662 |
| system | risk B2 | | Ecological resilience C5 | 0.148 |
| of the | | | Ecological | 0.191 |
| constructed | | | vulnerability C6 | |
| cascade | Shipping | 0.157 | Shipping reliability C7 | 0.076 |
| reservoirs | risk B3 | | Shipping resilience C8 | 0.016 |
| | | | Shipping | 0.907 |
| | | | vulnerability C9 | |
| | Water | 0.356 | Water storage | 0.022 |
| | storage | | reliability C10 | |
| | risk B4 | | Water storage | 0.017 |
| | | | resilience C11 | |
| | | | Water storage | 0.961 |
| | | | vulnerability C12 | |

Advantageous Effects: the risk can be evaluated from the perspective of the probability of risk occurrence, the consequences of risk events and the process of event resilience. The reservoir risk can be evaluated scientifically considering various uncertainties to help the sustainable development and utilization of water resources and further enhance the level of reservoir risk management.

The above detailed description further elaborates the purpose, technical solutions and beneficial effects of the invention. It should be understood that the above are only detailed description of the invention, and are not intended to limit the scope of protection of the invention. Any modification, equivalent replacement, improvement, etc. made within the spirit and principles of the invention shall be included in the protection scope of the invention.

1. A fuzzy cloud-based risk assessment method for reservoir operation schemes, comprising:
collecting basic data of target reservoirs, comprising: collecting an operation regulation, a relationship curve of a water level and a reservoir capacity, a relationship curve of a leakage flow and a tail water, and a discharge capacity curve of each discharge facility of the target reservoirs;
constructing an optimal operation model of conventional reservoirs to obtain model calculation results;
acquiring a change process of operation features during a whole operating period according to the model calculation results, and constructing a multi-level reservoir multi-dimensional risk assessment index system, comprising:
constructing the multi-level reservoir multi-dimensional risk assessment index system by a risk characterization method of reliability, resilience and vulnerability;
defining X, as a performance state in some aspect of an assessment object at a moment t; when a system performance is in a normal state NS, Xₜ is assigned to 1; when the system performance is in an impaired state FS, Xₜ is assigned to 0;
the reliability of the system in terms of performance in some aspect can be expressed as:
$$α = P [ {X}_{t} ∈ NS ] = \frac{{\sum }_{t = 1}^{T} {X}_{t}}{T} ; \qquad ( Formula 1 )$$
in the formula, α is a reliability index, and T is total time of a whole simulation period;
the resilience represents a possibility of the assessment object restored from the impaired state to the normal state, and the resilience is calculated according to the number of performance restoration in the operating period:
$$W ( t ) = \{ \begin{matrix}1 , & if {X}_{t} = 0 and {X}_{t + 1} = 1 \\ 0 , & otherwise\end{matrix} ; \qquad ( Formula 2 )$$
$$γ = \{ \begin{matrix}P [ {X}_{t + 1} ∈ NS \vert {X}_{t} ∈ FS ] = \frac{{\sum }_{t = 1}^{T} W ( t )}{T - {\sum }_{t = 1}^{T} X ( t )} & if α < 1 \\ 1 & if α = 1\end{matrix} ; \qquad ( Formula 3 )$$
in the formula, γ represents the resilience of the assessment object, and W(t) represents the number of times of system restoration; the performance restoration without impairment in the operating period is defined as 1;
a vulnerability index is a measure of a severity of a failure, expressed as an average of the maximum performance loss of all risk events over the entire operating period:
$$ϑ = \frac{{\sum }_{j = 1}^{M} {V}_{j}}{M} ; \qquad ( Formula 4 )$$
in the formula, v represents the vulnerability of the assessment object and Vⱼ represents the maximum loss of performance per risk event; M represents the total number of risk events in the whole simulation period;
dividing different risk level intervals according to the multi-level reservoir multi-dimensional risk assessment index system, comprising:
dividing different risk levels based on the multi-dimensional risk assessment index system of the constructed cascade reservoirs;
according to upper and lower boundaries of the different risk level intervals, determining cloud digital features (Eₓ, Eₙ, Hₑ) of the different risk levels and a Pythagoras fuzzy number <μ_{P}(x), v_{P}(x)> of the corresponding interval by a forward cloud generator (Formula 5):
$$\{ \begin{matrix}{E}_{x} = ( {U}_{min} + {U}_{max} ) / 2 \\ {E}_{n} = ( {U}_{max} - {U}_{min} ) / 6 \\ {H}_{e} = k \cdot {E}_{n}\end{matrix} ; \qquad ( Formula 5 )$$
in the formula, Ex refers to an expected distribution of cloud droplets in a domain space, which is a most representative point of a qualitative concept; En refers to a dispersion degree of the cloud droplets, which is a measurable granular representation of the qualitative concept; generally, the larger En is, the more macroscopic the qualitative concept is, that is, the greater the fuzziness of the qualitative concept is; He represents an uncertainty of an entropy; the greater the He is, the greater a thickness of the cloud droplets, and the greater the degree of the dispersion is, which indicates that simulation results are more random; Uₘᵢₙ and Uₘₐₓ respectively represent a minimum value and a maximum value of a risk level threshold; k represents an adjustment system for cloud droplet cohesion, and is usually taken as k=0.1 by default;
a large number of sample data xᵢⱼ of a reservoir risk index under corresponding working conditions are obtained by multiple parallel calculations to conduct a risk assessment;
wherein calculating the cloud digital features of different indexes by an inverse cloud generator comprises:
calculating the cloud digital features (Exᵢ, Enᵢ, Heᵢ) of different indexes by the inverse cloud generator (Formula 6);
determining the Pythagoras fuzzy number of each index of an index layer based on the risk level interval to which the sample data of the index layer belongs, and obtaining a Pythagoras fuzzy cloud PFCᵢ(<Exᵢ, μ_{Pi}(x), v_{Pi}(x)>, Enᵢ, Heᵢ) (i=1, 2, . . . , m) of different indexes of the index layer;
$$\{ \begin{matrix}{E}_{x} ( i ) = \frac{1}{n} {\sum }_{j = 1}^{n} {x}_{ij} \\ {E}_{n} ( i ) = \sqrt{\frac{π}{2}} \times \frac{1}{n} {\sum }_{j = 1}^{n} \vert {x}_{ij} - {E}_{x} ( i ) \vert \\ {H}_{e} ( i ) = \sqrt{\vert {S ( i )}^{2} - {{E}_{n} ( i )}^{2} \vert}\end{matrix} ( i = 1 , 2 , L , m ; j = 1 , 2 , L , n ) ; \qquad ( Formula 6 )$$
in the formula, xᵢⱼ is a value of the index in a j^{th} simulation result;
$${S ( i )}^{2} = \frac{1}{n - 1} {\sum }_{j = 1}^{n} {( {x}_{ij} - {E}_{x} ( i ) )}^{2}$$
represents a variance of a simulation sample; μ_{Pi}(x) is a membership value of the index i; v_{Pi}(x) is a non-membership value of the index i;
weighting the indexes in the index layer and a criterion layer by an Analytic Hierarchy Process (AHP), and respectively calculating the Pythagoras fuzzy cloud of each index in the criteria layer and a target layer to obtain multi-dimensional risk assessment results of a target working condition, comprising:
weighting the indexes in the index layer and the criterion layer by the Analytic Hierarchy Process (AHP), and respectively calculating the Pythagoras fuzzy cloud (Formula 7) of each index in the criteria layer and the target layer to obtain the multi-dimensional risk assessment results of the target working condition;
$$PFC ( {PFC}_{1} , {PFC}_{2} , … , {PFC}_{m} ) = {\sum }_{i = 1}^{m} {ω}_{i} {PFC}_{i} = ( < {\sum }_{i = 1}^{m} {ω}_{i} {Ex}_{i} , \frac{{\sum }_{i = 1}^{m} {ω}_{i} {μ}_{Pi} {Ex}_{i}}{{\sum }_{i = 1}^{m} {ω}_{i} {Ex}_{i}} , \frac{{\sum }_{i = 1}^{m} {ω}_{i} {v}_{Pi} {Ex}_{i}}{{\sum }_{i = 1}^{m} {ω}_{i} {Ex}_{i}} > , \sqrt{{\sum }_{i = 1}^{m} {{ω}_{i} ( {En}_{i} )}^{2}} , \sqrt{{\sum }_{i = 1}^{m} {{ω}_{i} ( {He}_{i} )}^{2}} ) ; \qquad ( Formula 7 )$$
in the formula, PFCᵢ represents the Pythagoras fuzzy cloud of the index i; ωᵢ represents a weight of the index i; Exᵢ represents the expected distribution of the cloud droplets of the index i, the point representing the qualitative concept; μ_{Pi} represents the membership of the index i; v_{Pi} represents the non-membership of the index i; Enᵢ represents the entropy of the index i to describe the degree of dispersion of the cloud droplets; and Heᵢ represents a super-entropy of the index i to describe the uncertainty of the qualitative concept.

2. The fuzzy cloud-based risk assessment method for reservoir operation schemes according to claim 1, wherein the constructing the optimal operation model of the conventional reservoirs to obtain the model calculation results specifically comprises:
constructing the optimal operation model of the conventional reservoirs, considering inflow conditions and engineering conditions that need risk assessment, and transforming same into constraint conditions or boundary input of the model; and
generating optimal operation schemes of reservoirs under corresponding working conditions by solving.

3. The fuzzy cloud-based risk assessment method for reservoir operation schemes according to claim 1, wherein the operation features during the whole operating period specifically comprise a reservoir discharged volume, a reservoir water level, an output and a water level variation.
